(19) United States
(12) Patent Application Publication
(10) Pub. No.: US 2006/0128120 A1
(43) Pub. Date: Jun. 15, 2006

(54) Short-wavelength laser dicing apparatus for a diamond wafer and dicing method thereof

(76) Inventor: Chih-Ming Hsu, Taoyuan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/211,678

(22) Filed: Aug. 26, 2005

(30) Foreign Application Priority Data
Dec. 14, 2004 (TW) 93138749

(51) Int. Cl. H01L 21/78

(52) U.S. Cl. 438/463; 438/464; 438/460

(57) ABSTRACT

The present invention discloses a short-wavelength laser dicing apparatus for a diamond wafer and a dicing method thereof, wherein a diamond wafer is disposed on a working table; the diamond wafer has multiple scribed lines; a control device is used to position the working table and a short-wavelength laser so that the short-wavelength laser can sequentially cut the scribed lines and the diamond wafer can be separated into multiple discrete chips or dice. The present invention utilizes the high-energy photons of a short-wavelength laser to enable a diamond wafer to be easily cut and can accelerate the cutting process.

### BACKGROUND OF THE INVENTION

1. Field of the Invention

The present invention relates to a dicing apparatus for a diamond wafer and a dicing method thereof, particularly to a short-wavelength laser dicing apparatus for a diamond wafer and a dicing method thereof.

2. Description of the Related Art

Diamond, also called bort in mineralogy, has the highest hardness, the highest thermal conductivity, the highest wear resistance and the highest compression strength among all materials. Diamond also has a high refractive index and a low thermal expansivity. For the comparisons between diamond and glass, if one licks a diamond and a glass with his tongue tip, he will feel cool from the diamond but not from the glass; if one expires a warm breath to fog a diamond and a glass, the fog on the diamond disappears quickly, but the fog on the glass disappears slowly; if one submerges a diamond and a glass into water, the diamond still looks clear, but the glass looks blurred and distorted.

English and Swedish scientists found that diamond is the best candidate for high-quality chips and had manufactured a diamond chip only four millimeters square. Such a chip can be used in high-level fields, such as radars or satellite communication devices.

It is well known that diamond is superior to silicon in hardness and heat resistance. Therefore, diamond chips function better than silicon chips in high temperature, high pressure and high frequency environments, and in some special industries, diamond chips obviously outperform silicon chips. The breakdown voltage of diamond chips is one hundred times that of silicon chips; further, diamond can endure high temperature and high pressure and has an incomparable hardness. Therefore, a diamond chip is the best choice for high-precision equipments, such as elements of radars or spaceships.

In the conventional technology, a diamond blade is usually used to cut a diamond chip. However, owing to the hardness of diamond, a diamond chip is hard to cut, and cutting a diamond chip is pretty time-consuming.

Accordingly, the present invention proposes a short-wavelength laser dicing apparatus for a diamond wafer and a dicing method thereof to overcome the abovementioned problems.

### SUMMARY OF THE INVENTION

The primary objective of the present invention is to provide a short-wavelength laser dicing apparatus for a diamond wafer and a dicing method thereof, wherein the pulse of a short-wavelength laser impacts a scribed line on a diamond wafer, and the high-energy photons of the short-wavelength laser break the molecular bonds between the carbons of the diamond wafer, and thus, the short-wavelength laser ablates some portion of the scribed line on the diamond wafer, and the diamond wafer is cut thereby.

Another objective of the present invention is to provide a short-wavelength laser dicing apparatus for a diamond wafer and a dicing method thereof, wherein a short-wavelength laser enables a diamond wafer to be easily and rapidly cut so that the cutting process is accelerated.

To achieve the abovementioned objectives, the present invention proposes a short-wavelength laser dicing apparatus for a diamond wafer, which comprises: a working table, having a vacuum device to fix a diamond wafer with multiple scribed lines drawn thereon; a short-wavelength laser, used to cut the diamond wafer; a light-guide device, directing the short-wavelength laser to the diamond wafer; and a control device, positioning the working table and the short-wavelength laser to enable the short-wavelength laser to be precisely aimed at one of the scribed lines on the diamond wafer for cutting the diamond wafer.

The present invention also proposes a short-wavelength laser dicing method for a diamond wafer, which comprises the following steps: firstly, providing a diamond wafer with multiple scribed lines drawn thereon; next, disposing the diamond wafer on a working table; next, utilizing a control device to position the working table and a short-wavelength laser to enable the short-wavelength laser to be precisely aimed at one of the scribed lines; next, inputting the length of the scribed line to be cut and the spacing between the scribed line to be cut and another scribed line to be cut next; and lastly, sequentially cutting the scribed lines for dicing the diamond wafer.

To enable the objectives, technical contents, characteristics and accomplishments of the present invention to be more easily understood, the embodiments of the present invention are to be described below in detail in cooperation with the attached drawings.

### BRIEF DESCRIPTION OF THE DRAWINGS

FIG. 1 is a block diagram schematically showing the short-wavelength laser dicing apparatus for a diamond wafer according to the present invention.

FIG. 2 is a flowchart of the short-wavelength laser dicing method for a diamond wafer according to the present invention.

### DETAILED DESCRIPTION OF THE INVENTION

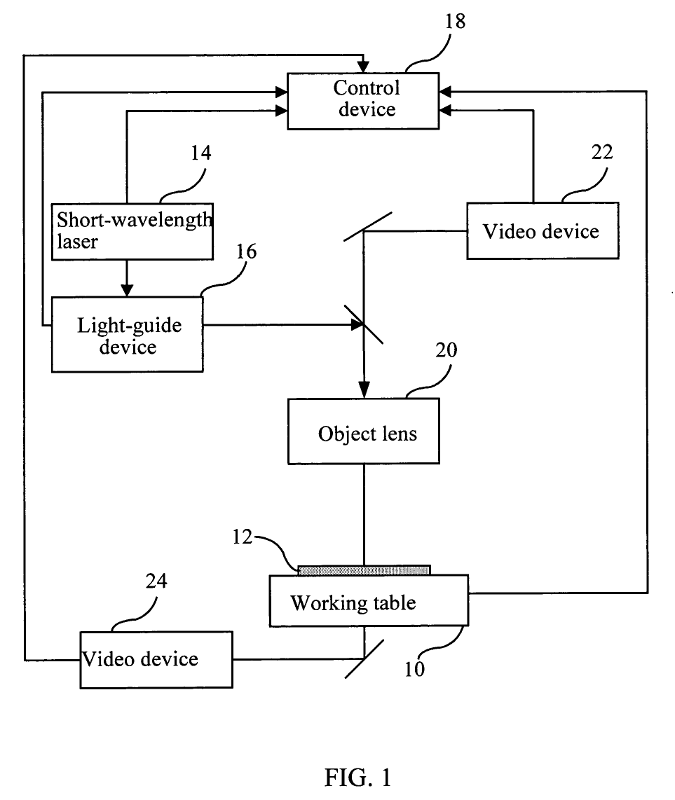

Refer to FIG. 1 a block diagram schematically showing the short-wavelength laser dicing apparatus for a diamond wafer according to the present invention. The short-wavelength laser dicing apparatus for a diamond wafer according to the present invention comprises: a working table 10, having a vacuum device (not shown in the drawing) to fixedly suck a diamond wafer 12 with multiple scribed lines drawn thereon, wherein the diamond wafer 12 may be stuck onto a holding film beforehand, and then, the diamond wafer 12 together with the holding film is disposed on the working table 10; a short-wavelength laser 14, having a wavelength ranging from 150 to 380 nm, and used to cut the diamond 12; a light-guide device 16, directing the short-wavelength laser 14 to the diamond wafer 12; and a control device 18, coupled to the working table 10, the short-wavelength laser 14 and the light-guide device 16, and positioning the working table 10 and the short-wavelength laser 14 to enable the short-wavelength laser 14 to be precisely aimed at one of the scribed lines on the diamond wafer 12.

The short-wavelength laser dicing apparatus for a diamond wafer according to the present invention may further comprises a focal-length-adjust element, which is installed on an object lens 20, wherein the object lens 20 is disposed between the diamond wafer 12 and the short-wavelength laser 14, and uses the focal-length-adjust element to adjust the focal length by which the short-wavelength laser 14 is to be aimed at one of the scribed lines on the diamond wafer 12. The short-wavelength laser dicing apparatus for a diamond wafer according to the present invention may further comprises two video devices 22, 24, which are separately disposed above and below the working table 10 to observe whether the short-wave length laser 14 has been precisely aimed at one of the scribed lines on the diamond wafer 12 when the control device 18 is positioning the working table 10 and the short-wavelength laser 14.

In the present invention, the short-wavelength laser has the following parameters; a frequency ranging from 20 to 80 KHz, an energy density ranging from 10 to 100 J/cm², a pulse duration ranging from 10 to 40 nanosecond, a beam diameter ranging from 10 to 30 μm. The short-wavelength laser having the parameters within the abovementioned ranges can emit photons of higher energy to cut a diamond wafer.

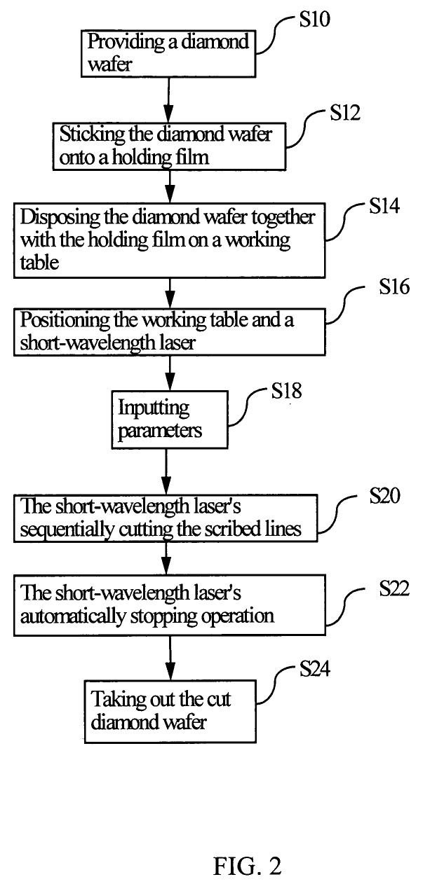

Refer to FIG. 2 a flowchart of the short-wavelength laser dicing method for a diamond wafer according to the present invention. The short-wavelength laser dicing method for a diamond wafer according to the present invention comprises the following steps: firstly, providing a diamond wafer with multiple scribed lines drawn thereon (S10); next, sticking the diamond wafer onto a holding film for flattening the diamond wafer (S12); next, disposing the diamond wafer together with the holding film on a working table, which has a vacuum device to fixedly suck the diamond wafer (S14); next, positioning the working table and a short-wavelength laser, and utilizing a control device to adjust the X and Y coordinates of the working table, and utilizing an object lens with a focal-length-adjust element to adjust the focal length by which the short-wavelength laser is to be aimed at one of the scribed lines on the diamond wafer (S16); next, inputting into the control device the length of the scribed line to be cut and the spacing between the scribed line to be cut and another scribed line to be cut next (S18); and next, initiating the short-wavelength laser to sequentially cut the scribed lines with a cut depth larger than one tenth of the thickness of the diamond wafer (S20); after finishing the cutting, the short-wavelength laser's automatically stopping operation (S22); and lastly, shutting the vacuum device of the working table, and taking out the diamond wafer, which has been cut well (S24).

In summary, the present invention proposes a short-wavelength laser dicing apparatus for a diamond wafer and a dicing method thereof, wherein the pulse of a short-wavelength laser impacts a scribed line on a diamond wafer, and the high-energy photons of the short-wavelength laser break the molecular bonds between the carbons of the diamond wafer, and thus, the short-wavelength laser ablates some portion of the scribed line on the diamond wafer, and the diamond wafer is cut thereby. The present invention utilizes a short-wavelength laser, which enables a diamond wafer to be easily and rapidly cut. Accordingly, the cutting process is accelerated.

Those embodiments described above are only to clarify the present invention in order to enable the persons skilled in the art to understood, make and use the present invention but not intended to limit the scope of the present invention. Any equivalent modification and variation according to the spirit of the present invention disclosed herein is to be included within the scope of the claims stated below.

What is claimed is:

1. A short-wavelength laser dicing apparatus for a diamond wafer, comprising:
a working table, having a vacuum device to fix a diamond wafer with multiple scribed lines drawn thereon;
a short-wavelength laser, used to cut said scribed lines;
a light-guide device, directing said short-wavelength laser to one of said scribed lines on said diamond wafer;
a control device, coupled to said working table, said short-wavelength laser and said light-guide device, and positioning said working table and said short-wavelength laser to enable said short-wavelength laser to be precisely aimed at one of said scribed lines on said diamond wafer.

2. The short-wavelength laser dicing apparatus for a diamond wafer according to claim 1, wherein said diamond wafer is stuck onto a holding film.

3. The short-wavelength laser dicing apparatus for a diamond wafer according to claim 1, wherein the wavelength of said short-wavelength laser ranges from 150 to 380 nm.

4. The short-wavelength laser dicing apparatus for a diamond wafer according to claim 1, further comprising at least one video device to observe whether said short-wavelength laser has been precisely aimed at one of said scribed lines on said diamond wafer.

5. The short-wavelength laser dicing apparatus for a diamond wafer according to claim 4, wherein said video device is disposed above or below said working table.

6. The short-wavelength laser dicing apparatus for a diamond wafer according to claim 1, further comprising a focal-length-adjust element that is disposed between said working table and said short-wavelength laser, and used to adjust the focal length by which said short-wavelength laser is to be aimed at one of said scribed lines on said diamond wafer.

7. The short-wavelength laser dicing apparatus for a diamond wafer according to claim 6, wherein said focal-length-adjust element is installed on an object lens.

8. A short-wavelength laser dicing method for a diamond wafer, comprising the following steps:
providing a diamond wafer with multiple scribed lines drawn thereon;
disposing said diamond wafer on a working table;
position said working table and a short-wavelength laser to enable said short-wavelength laser to be precisely aimed at one said scribed line, which is to be cut;
inputting into a control device the length of one said scribed line to be cut and the spacing between said scribed line to be cut and another said scribed line to be cut next; and
said short-wavelength laser's sequentially cutting said scribed lines for dicing said diamond wafer.

9. The short-wavelength laser dicing method for a diamond wafer according to claim 8, further comprising a step of “sticking said diamond wafer onto a holding film” before said step of “disposing said diamond wafer on a working table”.

10. The short-wavelength laser dicing method for a diamond wafer according to claim 8, wherein said working table has a vacuum device to fix said diamond wafer.

11. The short-wavelength laser dicing method for a diamond wafer according to claim 8, wherein said control device is used to position said working table and said short-wavelength laser.

12. The short-wavelength laser dicing method for a diamond wafer according to claim 8, wherein a focal-length-adjust element is used to adjust the focal length by which said short-wave length laser is to be aimed at one of said scribed line on said diamond wafer.

13. The short-wavelength laser dicing method for a diamond wafer according to claim 8, wherein said short-wavelength laser cuts said scribed lines into a depth lager than one tenth of the thickness of said diamond.

14. The short-wavelength laser dicing method for a diamond wafer according to claim 8, further comprising a step of “said short-wavelength laser's automatically stopping operation” after said step of “sequentially cutting said scribed lines”.

15. The short-wavelength laser dicing method for a diamond wafer according to claim 8, further comprising a step of “shutting said vacuum device, and taking out said diamond wafer” after said step of “said short-wavelength laser's automatically stopping operation”.
